(19) United States
(12) Patent Application Publication
(10) Pub. No.: US 2021/0376202 A1
(43) Pub. Date: Dec. 2, 2021

(54) MICRO LIGHT EMITTING DIODE AND METHOD FOR MANUFACTURING THE SAME, AND MICRO LIGHT EMITTING DIODE MODULE

(71) Applicant: CHONGQING KONKA PHOTOELECTRIC TECHNOLOGY RESEARCH INSTITUTE CO., LTD., Chongqing (CN)

(72) Inventors: Chen HUNG-WEN, Chongqing (CN); Kai Lun WANG, Chongqing (CN)

(21) Appl. No.: 17/343,126

(22) Filed: Jun. 9, 2021

Related U.S. Application Data
(63) Continuation of application No. PCT/CN2019/122818, filed on Dec. 3, 2019.

(51) Int. Cl. H01L 33/52; H01L 25/075

(52) U.S. Cl. CPC H01L 33/52; H01L 2933/005; H01L 25/0753

(57) ABSTRACT

A micro-LED and a method for manufacturing the same, and a micro-LED module are provided. The method includes the following. Multiple micro-LED units that are spaced on a substrate are provided. A jig is covered on the substrate in such a manner that a light-emitting part of each micro-LED unit is covered between the jig and the substrate. A molten light blocking material is injected into the jig in such a manner that the light blocking material is filled between side surfaces of each micro-LED unit and the jig. The light blocking material is cured to form a light blocking layer on the side surfaces of each micro-LED unit. The jig is removed after the light blocking material is cured.

### CROSS-REFERENCE TO RELATED APPLICATION(S)

This application is a continuation of International Application No. PCT/CN2019/122818, filed on Dec. 3, 2019, the entire disclosure of which is hereby incorporated by reference in its entirety.

### TECHNICAL FIELD

This disclosure relates to the technical field of micro light emitting diodes (micro-LEDs), and particularly to a micro-LED and a method for manufacturing the same, and a micro-LED module.

### BACKGROUND

Micro-LEDs, i.e., LEDs of miniaturization and matrix, have advantages of good stability, long service life, and operating temperatures. In addition, similar to the LED, the micro-LED also has the advantages of low power consumption, high color saturation, quick response, and strong contrast, or the like. Therefore, the micro-LED has good prospect, for example, the micro-LED is widely used in micro-LED displays.

During manufacturing of the micro-LED display, micro-LEDs on a growth substrate need to be transferred and fixed to a back panel of the display. After the micro-LEDs are transferred and fixed to the back panel of the display, light emitted by adjacent micro-LEDs of three colors (red, blue, and green) may be affected by each other, thereby affecting the contrast of the micro-LED display. Therefore, how to improve the contrast and display effect of the micro-LED display during manufacturing of the micro-LED display is a problem to be solved.

### SUMMARY

According to a first aspect, a method for manufacturing a micro-LED is provided. The method includes the following. Multiple micro-LED units that are spaced on a substrate are provided. A jig is covered on the substrate in such a manner that a light-emitting part of each micro-LED unit is covered between the jig and the substrate. A molten light blocking material is injected into the jig in such a manner that the light blocking material is filled between side surfaces of each micro-LED unit and the jig. The light blocking material is cured to form a light blocking layer on the side surfaces of each micro-LED unit. The jig is removed after the light blocking material is cured.

According to a second aspect, a micro-LED is provided. The micro-LED is configured to be mounted on a target substrate. The micro-LED includes a light-emitting part and a light blocking layer. The light blocking layer is coated on side surfaces of the light-emitting part, to define a first empty region and a second empty region on two opposite ends of the light-emitting part of the micro-LED.

According to a third aspect, a micro-LED module is provided. The micro-LED module includes substrate, multiple micro-LED units arranged on the substrate, and a light blocking layer. The light blocking layer is coated on side surfaces of each micro-LED unit, to define a first empty region and a second empty region on two opposite ends of each micro-LED unit. The first empty region faces the substrate and is attached to the substrate, and the second empty region is away from the substrate.

### BRIEF DESCRIPTION OF THE DRAWINGS

FIG. 1 is a schematic structural diagram illustrating a display device according to implementations of the disclosure.

FIG. 2 is a schematic structural diagram illustrating a display assembly according to implementations of the disclosure.

FIG. 3 is a schematic diagram illustrating a micro-LED module according to implementations of the disclosure.

FIG. 4 is a flow chart illustrating a manufacturing method according to a first implementation of the disclosure.

FIG. 5 is a flow chart illustrating a manufacturing method according to a second implementation of the disclosure.

FIG. 6 is a flow chart illustrating a manufacturing method according to a third implementation of the disclosure.

FIG. 7 is a schematic diagram illustrating a manufacturing process according to a first implementation of the disclosure.

FIG. 8 is a schematic diagram illustrating a manufacturing process according to a second implementation of the disclosure.

FIG. 9 is a schematic diagram illustrating a manufacturing process according to a third implementation of the disclosure.

FIG. 10 is a schematic sub-flow chart illustrating a first example according to a first implementation of the disclosure.

FIG. 11 is a schematic sub-flow chart illustrating a second example according to a first implementation of the disclosure.

FIG. 12 is a schematic diagram illustrating a sub-process of a second example according to a first implementation of the disclosure.

FIG. 13a and FIG. 13b are schematic diagrams illustrating a micro-LED according to a first implementation of the disclosure.

FIG. 14 is a schematic diagram illustrating a micro-LED according to a second implementation of the disclosure.

FIG. 15 is a schematic diagram illustrating a LED according to a third implementation of the disclosure.

### DETAILED DESCRIPTION

In order to describe contents of the disclosure more clearly and accurately, a detailed description will be given with reference to the accompanying drawings. The accompanying drawings of the specification illustrate exemplary implementations, in which the same reference numerals represent same elements. It can be understood that the accompanying drawings of the specification is merely for illustrative purpose and are not drawn in scale.

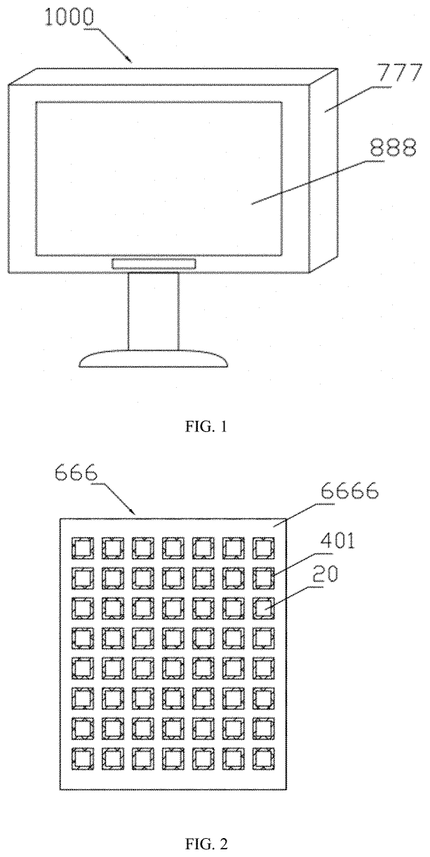

FIG. 1 is a schematic structural diagram illustrating a display device 1000 according to implementations of the disclosure. FIG. 2 is a schematic structural diagram illustrating a display assembly 666 according to implementations of the disclosure. The display device 1000 is a product with a display function, such as a laptop computer, a tablet computer, a display, a television, a mobile phone, and so on. The display device 1000 includes the display assembly 666, a housing 777, and a display panel 888. The display assembly 666 is received between the housing 777 and the display panel 888. The display assembly 666 includes a back panel 6666 and multiple micro-LEDs arranged on the back panel 6666.

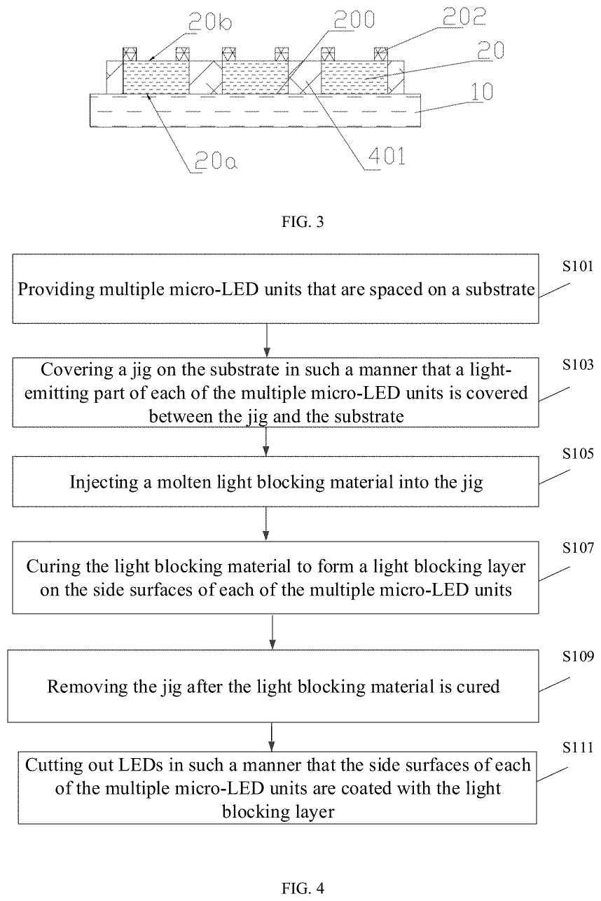

FIG. 3 is a schematic diagram illustrating a micro-LED module 100 according to implementations of the disclosure. The micro-LED module 100 includes a substrate 10, multiple micro-LED units 20, and a light blocking layer 401. The multiple micro-LED units 20 are arranged on the substrate 10. The light blocking layer 401 is coated on side surfaces of each micro-LED unit 20, to define a first empty region 20a on one end of two opposite ends of the micro-LED unit 20 and a second empty region 20b on the other end of the two opposite ends opposite to the one end of the two opposite ends. The first empty region 20a faces the substrate 10 and is attached to the substrate 10. The second empty region 20 b is away from the substrate 10. Each micro-LED unit 20 is provided with electrodes 202. The electrodes 202 are located in the first empty region 20a, or in the second empty region 20b. Alternatively, one of the electrodes 202 is located in the first empty region 20a and the other of the electrodes 202 is located in the second empty region 20b. A positional relationship among the electrodes 202 of the micro-LED unit 20, the first empty region 20a, and the second empty region 20b is determined according to the shape of the micro-LED unit 20. The detailed contents will be described below.

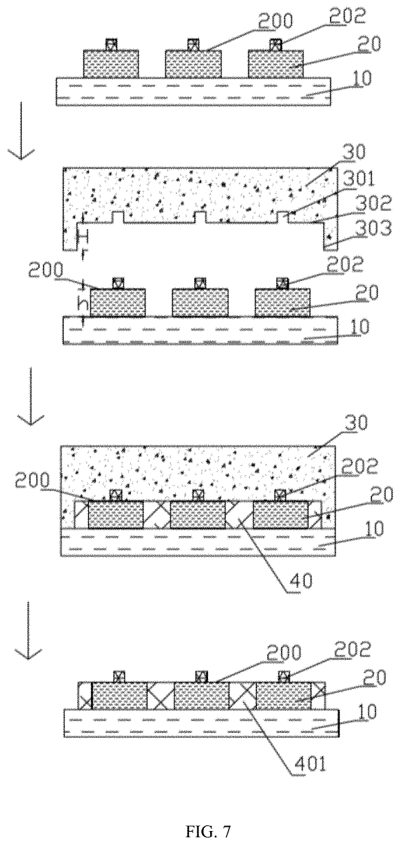

FIG. 4 is a flow chart illustrating a manufacturing method according to a first implementation of the disclosure. FIG. 7 is a schematic diagram illustrating a manufacturing process according to a first implementation of the disclosure. The method in the first implementation is used for manufacturing a LED 99 from the multiple micro-LED units 20 formed on the substrate 10. The method begins at S101.

At S101, multiple micro-LED units 20 that are spaced on a substrate 10 are provided. In one example, the multiple micro-LED units 20 are arranged in an array. There are gaps among the multiple micro-LED units 20.

At S103, a jig 30 is covered on the substrate 10 in such a manner that a light-emitting part 201 of each micro-LED unit 20 is covered between the jig 30 and the substrate 10. In one example, when the jig 30 is covered on the substrate 10, one side of each micro-LED unit 20 away from the substrate 10 is firmly attached to the jig 30, or one side of each micro-LED unit 20 close to the substrate 10 is firmly attached to the substrate 10. There is a gap between outmost micro-LED units of the multiple micro-LED units 20 and the jig 30. A positional relationship among the multiple micro-LED units 20, the substrate 10, and the jig 30 is determined according to the shapes of the multiple micro-LED units 20. The micro-LED units 20 of different shapes correspond to different jigs 30. In addition, when the micro-LED units 20 of different shapes are provided, different methods can be adopted. The detailed contents will be described below.

At S105, a molten light blocking material 40 is injected into the jig 30 in such a manner that the light blocking material is filled between side surfaces of each micro-LED unit 20 and the jig 30. The light blocking material 40 is black glue, i.e., black opaque epoxy resin.

At S107, the light blocking material 40 is cured to form a light blocking layer 401 on the side surfaces of each micro-LED unit 20.

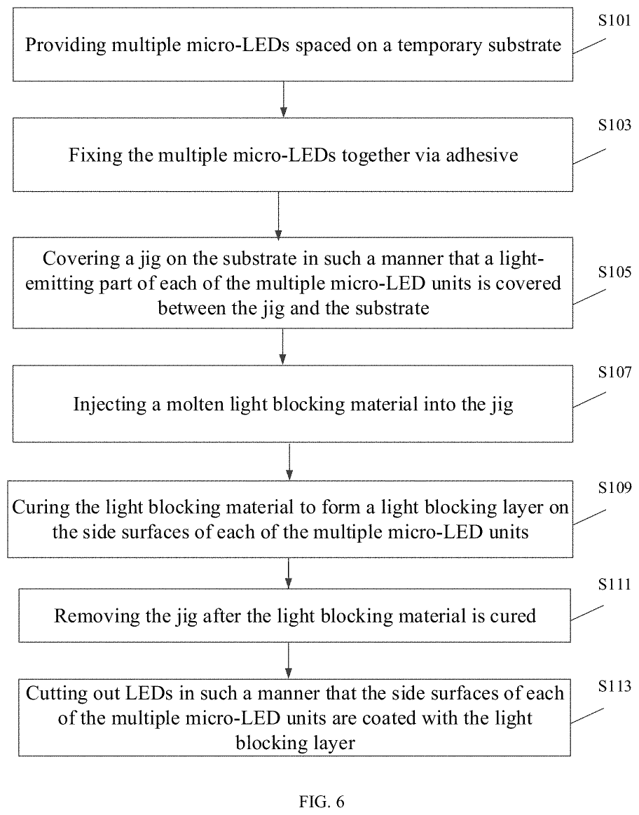

At S109, the jig 30 is removed after the light blocking material 40 is cured. As illustrated in FIG. 6, after the jig 30 is removed, the light blocking material 40 is coated on side surfaces of each of outmost micro-LED units 20 and filled in gaps among the multiple micro-LED units 20. That is, the light blocking layer 401 is formed on the side surfaces of each micro-LED unit 20.

At S111, LEDs 99 are cut out such that the side surfaces of each micro-LED unit 20 are coated with the light blocking layer 401. In one example, the multiple micro-LED units 20 coated with the light blocking layer 401 can be cut according to actual needs to obtain LEDs 99 of proper sizes.

Alternatively, the operations at S111 can be omitted. Cutting is not carried out until further processing is required.

In the above first implementation, glue is injected into the jig to be coated on the side surfaces of each micro-LED unit, which greatly reduces uneven coating and improves the accuracy and stability of the glue injected.

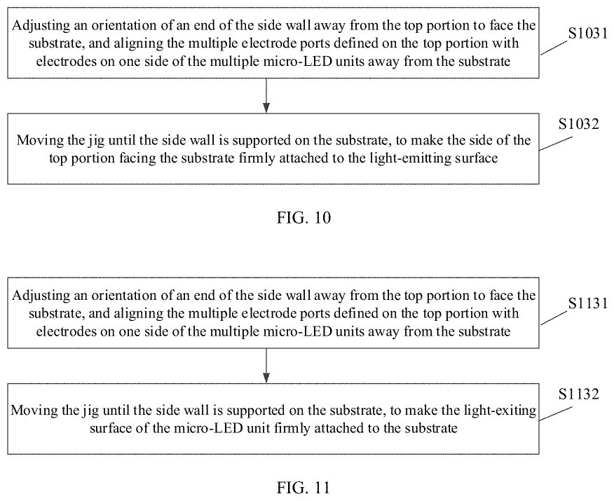

FIG. 10 is a schematic sub-flow chart illustrating operations at S103 of a first example according to a first implementation of the disclosure. In the first example, each micro-LED unit 20 is a vertical structure and has a light-exiting surface 200 away from the substrate 10. The jig 30 includes a top portion 302 and a side wall 303 extending from an edge of the top portion 302. The top portion 302 defines multiple electrode ports 301. Height H between one side of the top portion 302 facing the substrate 10 and the substrate 10 is equal to height h between the light-exiting surface 200 of the micro-LED unit 20 and the substrate 10. In combination with FIG. 7, the operations at S103 include operation at S1031 and S1032. At S1031, an orientation of an end of the side wall 303 away from the top portion 302 is adjusted to face toward the substrate 10. The multiple electrode ports 301 defined on the top portion 302 are aligned with electrodes 202 on one side of the multiple micro-LED units 20 away from the substrate 10. At S1032, the jig 30 is moved until the side wall 303 of the jig 30 is supported on the substrate 10, to make the side of the top portion 302 facing the substrate 10 firmly attached to the light-emitting surface 200. There is a gap between outmost micro-LED units of the multiple micro-LED units 20 and the side wall 303.

In the above first example of the first implementation, glue is coated on the multiple micro-LED units by adopting the jig that matches the multiple micro-LED units of the vertical structure so that the light blocking layer formed is suitable.

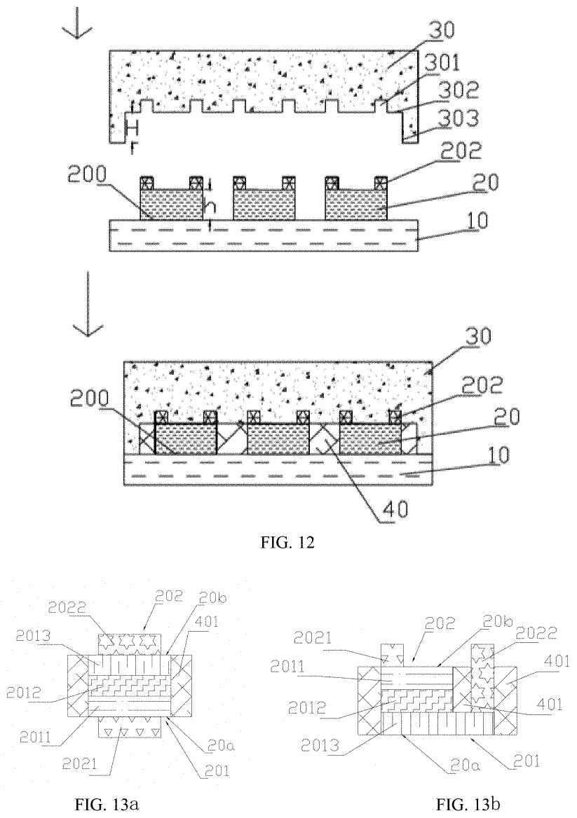

FIG. 11 is a schematic sub-flow chart illustrating operations at S103 of a second example according to a first implementation of the disclosure. The method in the second example of the first implementation is used for manufacturing a LED 999 from multiple micro-LED units 20 formed on the substrate 10. The method in the second example differs from the method in the first example in that in the second example, each micro-LED unit 20 is a flip-chip structure and has a light-exiting surface 200 facing the substrate 10. Height H between one side of the top portion 302 facing the substrate 10 and the substrate 10 is equal to height h between the light-emitting part 201 of the micro-LED unit 20 away from the substrate 10 and the substrate 10. As illustrated in FIG. 12, the operations at S103 include operations at S1131 and S1132. At S1131, an orientation of an end of the side wall 303 away from the top portion 302 is adjusted to face toward the substrate 10, and the multiple electrode ports 301 defined on the top portion 302 are aligned with electrodes 202 on one side of the multiple micro-LED units 20 away from the substrate 10. At S1132, the jig 30 is moved until the side wall 303 is supported on the substrate 10, to make the light-exiting surface 200 of the micro-LED unit 20 firmly attached to the substrate 10. There is a gap between outmost micro-LED units of the multiple micro-LED units 20 and the side wall 303 of the jig 30. Other operations in the method for manufacturing the LED 999 are substantially the same as those in the method for manufacturing the LED 99, which are not repeated herein.

In the above second example of the first implementation, glue is coated on the multiple micro-LED units by adopting the jig that matches the multiple micro-LED units of the flip-chip structure so that the light blocking layer formed is suitable.

In the above first implementation, the substrate 10 is a seed substrate (i.e., growth substrate). The light blocking layer 401 is made when the multiple micro-LED units 20 are on the growth substrate. Alternatively, since the electrodes 202 of the multiple micro-LED units 20 are located on a same side of light-emitting parts 201 of the multiple micro-LED units 20, the substrate 10 can be a temporary substrate, that is, the light blocking layer 401 is made after the multiple micro-LED units 20 are transferred from the growth substrate to the temporary substrate.

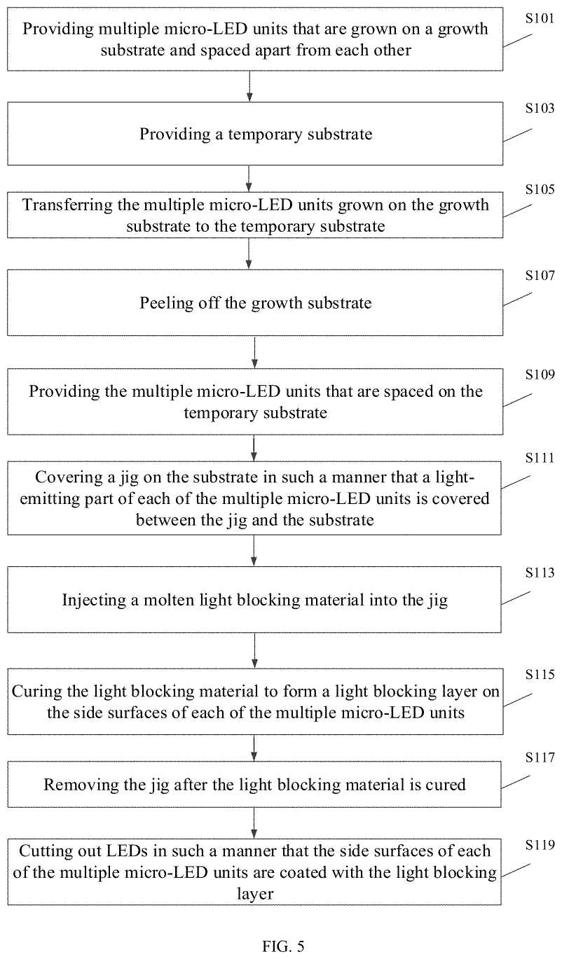

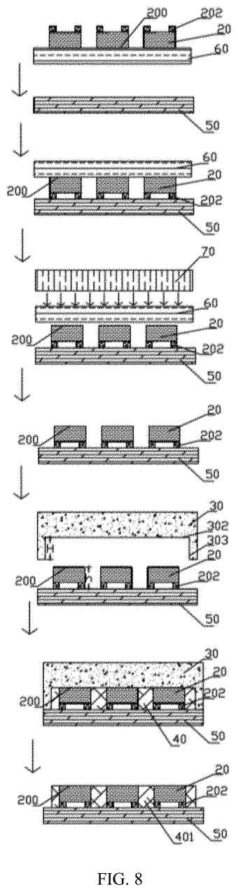

FIG. 5 is a flow chart illustrating a manufacturing method according to a second implementation of the disclosure. FIG. 8 is a schematic diagram illustrating a manufacturing process according to a second implementation of the disclosure. The method in the second implementation is used for manufacturing a LED 9999 from the multiple micro-LED units 20 formed on the substrate 10. In the second implementation, multiple micro-LED units 20 of a flip-chip structure are illustrated, and the light blocking layer 401 is made on a temporary substrate 50. That is, before providing the multiple micro-LED units 20 that are spaced on the temporary substrate 50, it is necessary to transfer the multiple micro-LED units 20 to the temporary substrate 50. The method begins at S101.

At S101, the multiple micro-LED units 20 are provided, where the multiple micro-LED units 20 are grown on a growth substrate 60 and spaced apart from each other. In one example, the multiple micro-LED units 20 are arranged in an array, and there are gaps among the multiple micro-LED units 20. Electrodes 202 of the multiple micro-LED units 20 are away from the growth substrate 60.

At S103, the temporary substrate 50 is provided.

At S105, the multiple micro-LED units 20 grown on the growth substrate 60 are transferred to the temporary substrate 50 and the electrodes 202 of the multiple micro-LED units 20 are arranged on the temporary substrate 50. In one example, the temporary substrate 50 is arranged on one side of the multiple micro-LED units 20 away from the growth substrate 60, to enable the electrodes 202 of the multiple micro-LED units 20 facing the temporary substrate 50.

At S107, the growth substrate 60 is peeled off. The growth substrate 60 is peeled off with a peeling device 70. The peeling device 70 may be, but is not limited to, a heating device, an ultraviolet device, or a laser device. In one example, the growth substrate 60 is heated, for example, the growth substrate 60 is peeled off by using a heating device to heat the growth substrate 60 at one side of the growth substrate 60 away from the multiple micro-LED units 20. Alternatively, the growth substrate 60 is irradiated with ultraviolet rays, for example, the growth substrate 60 is peeled off by using an ultraviolet device to emit ultraviolet rays to irradiate the growth substrate 60 at one side of the growth substrate 60 away from the multiple micro-LED units 20. Alternatively, the growth substrate 60 is irradiated with laser light, for example, the growth substrate 60 is peeled off by using a laser device to emit laser light to irradiate the growth substrate 60 at one side of the growth substrate 60 away from the multiple micro-LED units 20.

Other operations in the method for manufacturing the LED 9999 are substantially the same as those in the method for manufacturing the LED 99, which are not repeated herein.

In the second implementation, before injecting glue into the jig in such a manner that the glue is coated on the multiple micro-LED units of the flip-chip structure, the multiple micro-LED units are first transferred to the temporary substrate, and the side of the multiple micro-LED units without electrodes is allowed to be attached to the jig. As such, it is unnecessary to define the electrode ports on the jig, which is beneficial to alignment between the jig and the multiple micro-LED units, thereby simplifying the manufacturing process.

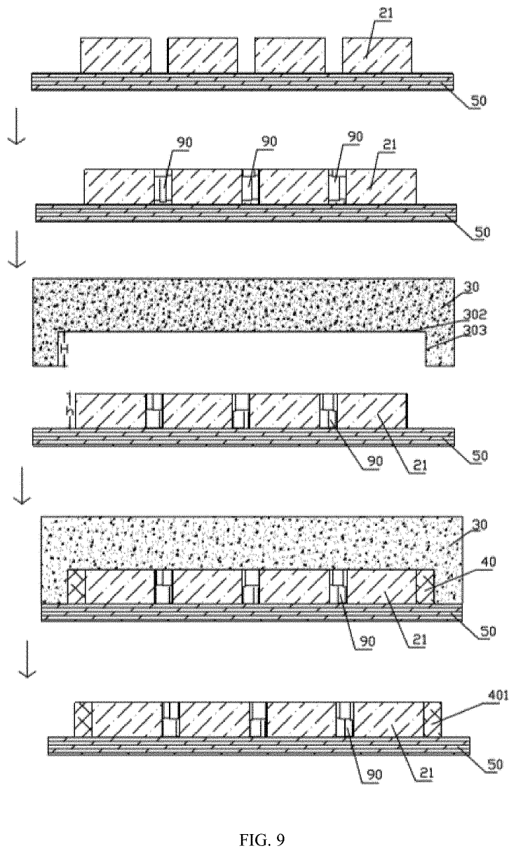

FIG. 6 is a flow chart illustrating a manufacturing method according to a third implementation of the disclosure. FIG. 9 is a flow chart illustrating a manufacturing method according to a third implementation of the disclosure. The method in the third implementation is used for manufacturing a LED 99999 from the multiple micro-LED units 20 formed on the substrate 10. The method in the third implementation differs from the method in the second implementation in that in the third implementation, each micro-LED unit 20 includes multiple micro-LEDs 21, and each of the multiple micro-LEDs 21 emits light of a same color. The multiple micro-LEDs 21 are spaced on the temporary substrate 50. The multiple micro-LEDs 21 are fixed to one another via adhesive 90. That is, side surfaces of the multiple micro-LEDs 21 are fixed together via the adhesive 90. The adhesive 90 is made from cold decomposition glue. Other operations in the method for manufacturing the LED 99999 are substantially the same as those in the method for manufacturing the LED 9999, which are not repeated herein.

In some implementations, before curing the light blocking material 40 to form the light blocking layer 401 on the side surfaces of each micro-LED unit 20, the multiple micro-LEDs 21 are fixed to one another via the adhesive 90.

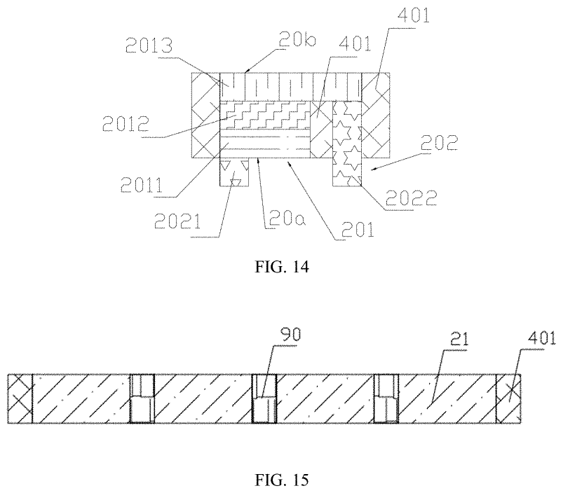

FIG. 13a and FIG. 13b are schematic diagrams illustrating a micro-LED according to a first implementation of the disclosure. FIG. 14 is a schematic diagram illustrating a micro-LED according to a second implementation of the disclosure. The micro-LED includes a light-emitting part 201 and a light blocking layer 401. The light blocking layer 401 is coated on side surfaces of the light-emitting part 201, to define a first empty region 20a and a second empty region 20b on two opposite ends of the light-emitting part 201 of the micro-LED. In one example, the light-emitting part 201 includes a first conductive semiconductor layer 2011, an active layer 2012, and a second conductive semiconductor layer 2013. The active layer 2012 is formed on the first conductive semiconductor layer 2011, and the second conductive semiconductor layer 2013 is formed on the active layer 2012. The electrodes 202 include a first electrode 2021 and a second electrode 2022.

As illustrated in FIG. 13a, the micro-LED 99 is a vertical structure. The micro-LED is provided with the first electrode 2021 and the second electrode 2022. The first electrode 2021 is located in the first empty region 20a and the second electrode 2022 is located in the second empty region 20b. The first electrode 2021 is formed on one side of the first conductive semiconductor layer 2011 away from the active layer 2012. The second electrode 2022 is formed on one side of the second conductive semiconductor layer 2013 away from the active layer 2012.

As illustrated in FIG. 13b, the micro-LED 999 is a flip-chip structure. The micro-LED is provided with the first electrode 2021 and the second electrode 2022. The first electrode 2021 and the second electrode 2022 are both located in the second empty region 20b. The first electrode 2021 is formed on one side of the first conductive semiconductor layer 2011 away from the active layer 2012. The second electrode 2022 is formed on one side of the second conductive semiconductor layer 2013 facing the first electrode 2021. An end of the second electrode 2022 extends beyond the first conductive semiconductor layer 2011.

As illustrated in FIG. 14, the micro-LED 9999 is a flip-chip structure. The micro-LED is provided with the first electrode 2021 and the second electrode 2022, both of which are located in the first empty region 20a. In one example, the first electrode 2021 is formed on one side of the first conductive semiconductor layer 2011 away from the active layer 2012. The second electrode 2022 is formed on one side of the second conductive semiconductor layer 2013 facing the first electrode 2021. An end of the second electrode 2022 extends beyond the first conductive semiconductor layer 2011.

FIG. 15 is a schematic diagram illustrating a LED 99999 according to a third implementation of the disclosure. As illustrated in FIG. 15, each micro-LED 21 is a vertical structure or a flip-chip structure.

In the above implementations, since the light blocking material 40 is filled via the jig 30, the light blocking material 40 can be evenly coated on the side surfaces of each micro-LED unit 20, which improves the accuracy and stability of the coating of the light blocking material 40. Since the side surfaces of each micro-LED unit 20 are coated with the light blocking layer 401, the mutual influence of colors of light emitted by LEDs on the back panel may be reduced, thereby increasing the contrast of the display. In addition, during mounting the LEDs to a target substrate, whether a single LED is transferred or multiple LEDs are transferred as a whole, displacement or falling of the LED(s) caused by vibration or movement during transfer can be reduced, thereby increasing the transfer speed and improving the transfer yield.

It can be understood that, those skilled in the art can make various changes and modifications to the disclosure without departing from the spirit and scope of the disclosure. In this way, if the modifications and changes of the disclosure fall within the scope of the claims of the disclosure and their equivalent technologies, the disclosure is also intended to include the modifications and changes.

The foregoing merely illustrates some implementations of the disclosure, which are not intended to limit the scope of the disclosure. Therefore, equivalent changes made according to the claims of the disclosure still fall within the scope of the disclosure.

What is claimed is:

1. A method for manufacturing a micro light emitting diode (micro-LED), comprising:
providing a plurality of micro-LED units that are spaced on a substrate;
covering a jig on the substrate in such a manner that a light-emitting part of each of the plurality of micro-LED units is covered between the jig and the substrate;
injecting a molten light blocking material into the jig in such a manner that the light blocking material is filled between side surfaces of each of the plurality of micro-LED units and the jig;
curing the light blocking material to form a light blocking layer on the side surfaces of each of the plurality of micro-LED units; and
removing the jig after the light blocking material is cured.

2. The method of claim 1, further comprising:
cutting out micro-LEDs in such a manner that the side surfaces of each of the plurality of micro-LED units are coated with the light blocking layer.

3. The method of claim 1, wherein when the jig is covered on the substrate, one side of each of the plurality of micro-LED units away from the substrate is firmly attached to the jig and there is a gap between outmost micro-LED units of the plurality of micro-LED units and the jig.

4. The method of claim 3, wherein each of the plurality of micro-LED units is a vertical structure and has a light-exiting surface away from the substrate, wherein the jig comprises a top portion and a side wall extending from an edge of the top portion, wherein the top portion defines a plurality of electrode ports, and a height between one side of the top portion facing the substrate and the substrate is equal to that between the light-exiting surface and the substrate, wherein covering the jig on the substrate in such a manner that the light-emitting part of each of the plurality of micro-LED units is covered between the jig and the substrate comprises:
adjusting an orientation of an end of the side wall away from the top portion to face the substrate, and aligning the plurality of electrode ports defined on the top portion with electrodes on one side of the plurality of micro-LED units away from the substrate; and
moving the jig until the side wall is supported on the substrate, to make the side of the top portion facing the substrate firmly attached to the light-emitting surface.

5. The method of claim 1, wherein when the jig is covered on the substrate, one side of each of the plurality of micro-LED units close to the substrate is firmly attached to the substrate and there is a gap between outmost micro-LED units of the plurality of micro-LED units and the jig.

6. The method of claim 5, wherein each of the plurality of micro-LED units is a flip-chip structure and has a light-exiting surface facing the substrate, wherein the jig comprises a top portion and a side wall extending from an edge of the top portion, wherein the top portion defines a plurality of electrode ports, and a height between one side of the top portion facing the substrate and the substrate is equal to that between the side of each of the plurality of micro-LED units away from the substrate and the substrate, wherein covering the jig on the substrate in such a manner that the light-emitting part of each of the plurality of micro-LED units is covered between the jig and the substrate comprises:
adjusting an orientation of an end of the side wall away from the top portion to face the substrate, and aligning the plurality of electrode ports defined on the top portion with electrodes on one side of the plurality of micro-LED units away from the substrate; and
moving the jig until the side wall is supported on the substrate, to make the light-exiting surface firmly attached to the substrate.

7. The method of claim 1, wherein the substrate is a temporary substrate and each of the micro-LED units is a flip-chip structure, wherein the method further comprises:
prior to providing the plurality of micro-LED units that are spaced on the substrate,
providing the plurality of micro-LED units that are grown on a growth substrate and spaced apart from each other, wherein electrodes of the plurality of micro-LED units are away from the growth substrate;
providing the temporary substrate;
transferring the plurality of micro-LED units grown on the growth substrate to the temporary substrate, and arranging the electrodes on the temporary substrate; and
peeling off the growth substrate.

8. The method of claim 1, wherein each of the micro-LED units comprises a plurality of micro-LEDs, and each of the plurality of micro-LEDs emits light of a same color.

9. The method of claim 8, wherein the plurality of micro-LEDs are fixed to one another.

10. The method of claim 8, wherein the plurality of micro-LEDs are spaced on the temporary substrate, wherein the method further comprises:
prior to curing the light blocking material to form the light blocking layer on the side surfaces of each of the plurality of micro-LED units,
fixing the plurality of micro-LEDs together via adhesive.

11. A micro-LED, comprising:
a light-emitting part; and
a light blocking layer, wherein the light blocking layer is coated on side surfaces of the light-emitting part, to define a first empty region and a second empty region on two opposite ends of the light-emitting part of the micro-LED.

12. The micro-LED of claim 11, wherein the micro-LED is provided with a first electrode and a second electrode, and the first electrode and the second electrode are both located in the first empty region.

13. The micro-LED of claim 11, wherein the micro-LED is provided with a first electrode and a second electrode, and the first electrode and the second electrode are both located in the second empty region.

14. The micro-LED of claim 11, wherein the micro-LED is provided with a first electrode and a second electrode, the first electrode is located in the first empty region, and the second electrode is located in the second empty region.

15. The micro-LED of claim 11, wherein the light-emitting part comprises:
a first conductive semiconductor layer;
an active layer formed on the first conductive semiconductor layer; and
a second conductive semiconductor layer formed on the active layer, wherein the micro-further comprises a first electrode and a second electrode, wherein the first electrode is formed on one side of the first conductive semiconductor layer away from the active layer, and the second electrode is formed on one side of the second conductive semiconductor layer away from the active layer.

16. The micro-LED of claim 11, wherein the light-emitting part comprises:
a first conductive semiconductor layer;
an active layer formed on the first conductive semiconductor layer; and
a second conductive semiconductor layer formed on the active layer, wherein the micro-LED further comprises a first electrode and a second electrode, wherein the first electrode is formed on one side of the first conductive semiconductor layer away from the active layer, the second electrode is formed on one side of the second conductive semiconductor layer facing the first electrode, and an end of the second electrode extends beyond the first conductive semiconductor layer.

17. A micro-LED module, comprising:
a substrate;
a plurality of micro-LED units arranged on the substrate; and
a light blocking layer, wherein the light blocking layer is coated on side surfaces of each of the plurality of micro-LED units, to define a first empty region and a second empty region on two opposite ends of each of the plurality of micro-LED units, wherein the first empty region faces and is attached to the substrate, and the second empty region is away from the substrate.

18. The micro-LED module of claim 17, wherein each of the plurality of micro-LED units is provided with a first electrode and a second electrode, and the first electrode and the second electrode are both located in the first empty region.

19. The micro-LED module of claim 17, wherein each of the plurality of micro-LED units is provided with a first electrode and a second electrode, and the first electrode and the second electrode are both located in the second empty region.

20. The micro-LED module of claim 17, wherein each of the plurality of micro-LED units is provided with a first electrode and a second electrode, the first electrode is located in the first empty region, and the second electrode is located in the second empty region.
